(19) United States
(12) Patent Application Publication
(10) Pub. No.: US 2003/0227069 A1
(43) Pub. Date: Dec. 11, 2003

(54) Power semiconductor with variable parameters

(75) Inventors: Peter Streit, Widen (CH); Oscar Apeldoorn, Bettwil (CH); Peter Steimer, Unterehrendingen (CH)

Correspondence Address: BURNS DOANE SWECKER & MATHIS L L P, POST OFFICE BOX 1404, ALEXANDRIA, VA, 22313-1404, US

(73) Assignee: ABB Schweiz AG, Baden (CH)

(21) Appl. No.: 10/457,748

(22) Filed: Jun. 10, 2003

(30) Foreign Application Priority Data
Jun. 10, 2002 (EP) 02405467.8

(51) Int. Cl. H01L 29/00

(52) U.S. Cl. 257/500

(57) ABSTRACT

The power semiconductor device has a pn junction between two power electrodes (2, 3). A control electrode (4) is arranged in the region of one of the two power electrodes (3). A current can be fed in via the control electrode, which current can be used to raise the current through the power electrodes. As a result, the reverse current can be raised in the blocking state of the device.

This allows a plurality of the power semiconductor devices according to the invention to be connected in series without additional snubber circuitry for protection against overvoltages.

### DESCRIPTION

1. Technical Field

The invention concerns the field of power electronics. It relates to a power semiconductor device, in particular a power diode, in accordance with the preamble of patent claim 1.

2. Prior Art

High-power converter circuits comprise various power electronic devices, for example power diodes and controllable power semiconductors from the families of thyristors (GTO, gate turn-off thyristor; GCT, gate-commutated thyristor, described in EP 0 588 026) or bipolar transistors (insulated gate bipolar transistor, IGBT). The current can be recommutated actively onto different paths in the circuit. In this case, static and dynamic losses occur in the turn-off semiconductors and in the diodes.

As in all semiconductors, in diodes, too, the semiconductor parameters can be coordinated with one another in order to achieve static and dynamic data that are as attractive as possible. Such coordinations are based for example on:

carrier lifetime setting by electrons, gold, platinum or other recombination centers,

axially or laterally structured carrier lifetime,

special control of the carrier lifetime in the edge region,

emitter engineering of homogeneous type for influencing the plasma distribution in the on state, or

finely structured emitter configurations for current-density-dependent influencing of the plasma distribution in the on state.

For the diodes, it is primarily the turn-off behavior that is of importance. The greatest losses are produced during the transition from the conducting to the blocking state.

The minimization of the dynamic switching losses by corresponding design of the diode parameters leads to undesirable side effects:

the forward voltage of the diode and the associated static on-state losses rise,

during the transition from the conducting to the blocking state, the anode current can fall very rapidly to zero during the depletion of the charge in the device. In the converter circuit, the anode-cathode voltage, rising very rapidly as a result, leads to a high overvoltage (>6 kV), which can lead to the destruction of the various semiconductor devices.

Converter applications with very high operating voltages (DC link voltages of above 3.5 to 5 kV) require a plurality of diodes to be connected in series. The individual diodes have certain, slightly different deviations from the ideal diode, which means that slightly different semiconductor parameters result from diode to diode. This in turn has the effect that, when a plurality of diodes are connected in series, the transition from the conducting to the blocking state and also the subsequent switched-off state are particularly critical:

although the leakage current in the switched-off, blocking state is identical in all the diodes, the slightly different semiconductor parameters of the diodes mean that major differences may occur in the voltage loading of the individual diodes,

the reverse recovery time in the transition from the conducting to the blocking state differs slightly from diode to diode,

the reverse current (reverse recovery current) in the diodes may terminate abruptly, and the diodes may generate corresponding oscillations with dangerous overvoltages, the termination again differing slightly from diode to diode.

In order to compensate for these effects, in conventional converter circuits, a passive circuitry, the so-called snubber circuitry, is connected in parallel with the series circuit comprising a plurality of diodes. With its passive components, the snubber circuit (RC circuitry) ensures that, during a turn-off operation and in the subsequent switched-off state of the diodes, the different semiconductor parameters of the individual diodes do not lead to an impermissible voltage distribution over the individual diodes.

However, such a snubber circuit leads to undesirable side effects:

large losses are produced, to be precise independently of whether the semiconductor parameters differ greatly or are almost identical,

additional passive components subjected to high voltage loading are necessary, as a result of which

the outlay on circuitry increases considerably.

### BRIEF SUMMARY OF THE INVENTION

One object of the invention is to provide a power semiconductor device of the type mentioned in the introduction which can be operated independently of the individual semiconductor parameters and without additional passive protective circuitry, and which is suitable in particular for connection in series with a plurality of power semiconductor devices of the same type.

This object is achieved by means of a power semiconductor device in accordance with patent claim 1.

The heart of the invention is that the power semiconductor device comprises means for dynamically influencing the semiconductor parameters which characterize the deviation from the ideal diode by the feeding of current into a control electrode.

With these means, the leakage current in the power semiconductor device according to the invention cannot be reduced to zero, but it can be increased gradually. Thus, although the losses in the device are also additionally increased, this results in the lowest-loss matching of the individually different leakage currents of a series of power semiconductor devices connected in series, in that the leakage currents of all the power semiconductor devices are matched to the largest leakage current. The control currents to be applied are of the order of magnitude of the leakage currents.

Similar controls are also possible dynamically, so that differences in the reverse current peaks, the reverse recovery times and the charge to be depleted can also be compensated for by means of the control electrode. Moreover, the hard current chopping of conventional diodes can be entirely avoided by means of the control electrode.

In the switched-off blocking state of the power semiconductor device, a current of the order of magnitude of the maximum cathode current can be fed in momentarily via the control electrode. Depending on the circuit of a converter, it is thus possible that the power semiconductor device according to the invention becomes able to be connected in series in a simple manner not merely as an individual element, rather that it also performs the compensating function for further devices connected in parallel with it, e.g. as a freewheeling diode for a parallel GTO or IGBT. The overvoltages at the individual power semiconductors which arise due to differences in the switching behavior of the series-connected active power semiconductors can be limited by short-term acceptance of the current by the power semiconductor devices according to the invention.

Further advantageous embodiments emerge from the dependent claims.

### BRIEF DESCRIPTION OF THE DRAWINGS

Exemplary embodiments of the invention and further advantages that can be achieved therewith are explained in more detail below with reference to drawings, in which:

FIG. 1 shows a plan view of a first embodiment of the power semiconductor device according to the invention with a honeycomb-shaped control electrode/cathode structure,

FIG. 2 shows a plan view of a second embodiment of the power semiconductor device according to the invention with a circular cathode structure and a central control electrode,

FIG. 3 shows a perspective view in the direction of the arrow of the first embodiment sectioned along III-III in accordance with FIG. 1,

FIG. 4 shows a view in the direction of the arrow of the first embodiment sectioned along IV-IV in accordance with FIG. 1,

FIG. 5 shows measured values of measurements on a power semiconductor device according to the invention in steady-state operation in the blocking state at a junction temperature of 25° C.,

FIG. 6 shows measured values of measurements on a power semiconductor device according to the invention in a circuit antiparallel with respect to an active semiconductor element in steady-state operation in the blocking state,

FIG. 7 shows measured values of measurements on a power semiconductor device according to the invention in a circuit antiparallel with respect to an active semiconductor element in dynamic operation in the transition from the conducting to the blocking state, and

FIG. 8 shows a circuit symbol of the power semiconductor device according to the invention.

### WAY OF EMBODYING THE INVENTION

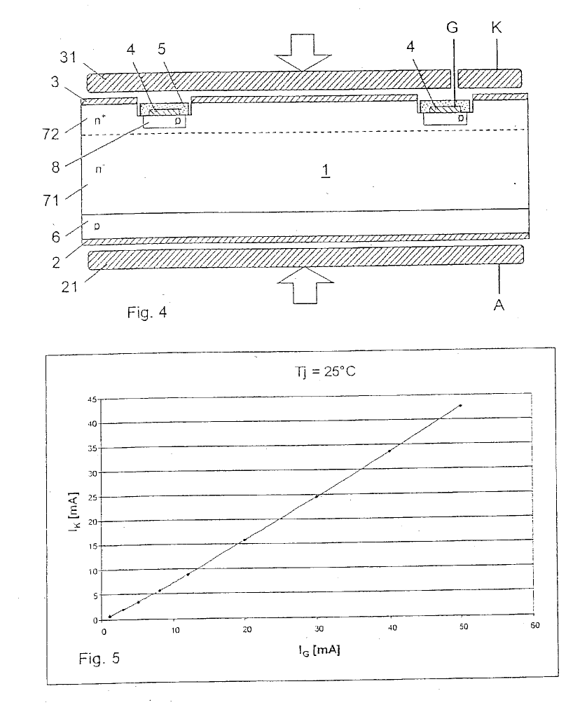

The construction of the power semiconductor device according to the invention is explained with reference to FIG. 4. The illustration shows a section through a first possible embodiment.

A semiconductor body 1, which is advantageously designed in the form of a wafer, can be contact-connected on both opposite main areas in a large-area manner via power electrodes. The figure illustrates the anode electrode 2 at the bottom on the first main area and the cathode electrode 3 lying opposite on the upper, second main area.

The semiconductor body 1, like a conventional power diode, is subdivided into two highly doped zones of different conductivity types which form a pn junction at their plane of intersection, one of the two zones having, in the region of the plane of intersection, a weakly doped central layer in which the space charge zone can propagate.

The first zone comprises an anodal p-doped layer 6, and the second zone comprises an inner n⁻-doped layer 71 and a cathodal n⁺-doped layer 72. The design of the dopings is advantageously chosen in accordance with conventional power diodes (high operating voltage, high switching frequencies and high switching currents).

The anodal p-doped layer 6 typically has an edge concentration of 5E+17 cm⁻³ of boron. The cathodal n⁺-doped layer 72 has an edge concentration of 1E+20 cm⁻³ of phosphorus. The inner, inner n⁻-doped layer 71 is usually dimensioned in a doping range of between 4E+12 and 1.2E+13 cm⁻³ of phosphorus in the case of high-voltage power diodes.

The cathode electrode 3 of the power semiconductor device according to the invention is divided into individual islands. A control electrode 4 provided on a p-doped layer 8 is provided in between. The control electrode layer 8 is completely embedded in the underlying n⁺-doped cathodal layer 72. Consequently, there is a highly doped region between the control electrode layer 8 and the inner, weakly doped layer 71.

The control electrode 4 is lowered relative to the cathode electrode 3. During the contact connection of the power electrodes by means of pressure plates 21 and 31, on the cathode side, all the electrode islands are connected to one another to form a single cathode electrode, while the lowered control electrode 4 remains electrically insulated from the pressure plate 31 by an insulation clearance and an additional insulation layer 5.

In the first embodiment of the power semiconductor device according to the invention, the control electrode 4 is designed as a finely distributed yet continuous electrode enclosing the cathode electrode islands 3. The control electrode 4 is led from the device laterally, for example between the second main area and the corresponding pressure plate, and contact-connected to an external terminal (not illustrated).

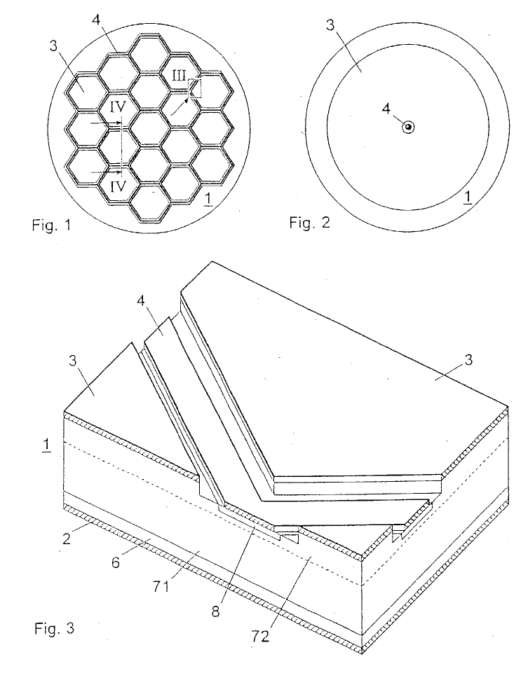

One possible structure of the cathodal second main area of the power semiconductor device according to the invention is illustrated in FIG. 1 in a plan view of the second main area from above. The cathode electrode islands 3 are of hexagonal design and surrounded by the finely structured control electrode 4.

FIG. 3 shows an enlarged detail from the embodiment in accordance with FIG. 1 with the large-area, hexagonal cathode electrode islands 3 and the control electrode 4 lying in between.

The cathode electrode 3 and the underlying n⁺-doped layer 72 are designed in large-area fashion such that they can carry the full load current continuously in the operating state. The cathode electrode 3 covers an area which is larger than the area covered by the control electrode 4. In an advantageous manner, the area covered by the cathode electrode 3 is at least 50% larger than the area covered by the control electrode 4.

The highly doped emitter layers 6 and 72 of the diode are essentially produced by known diode processes, the p-type emitter being realized by boron implantation in accordance with a preferred method and the n-type emitter by deposition of a phosphorus glass. Afterward, a structured silicon etching of defined depth is performed on the cathode in regions of the control electrode. In a final silicon process step, in the same control electrode region, boron is implanted and indiffused into the desired depth. The p-doped control electrode layer can be produced selectively by masked implantation or over the whole area, depending on whether or not a reverse-blocking property of the control electrode is required.

Since the complete embedding of the control electrode layer 8 in the n⁺-doped cathodal layer 72 constitutes an essential feature of the new diode structure, it has proved to be advantageous to form the layer 72 as a double profile in a two-stage step. In this case, in a first production process, phosphorus is implanted onto the cathode side and indiffused comparatively deeply. Afterward, the actual cathode emitter is provided by means of the chemical deposition of a phosphorus glass. Afterward, it is simple to perform the structured silicon etching in such a way that it completely penetrates through the heavily doped actual cathode emitter and essentially leaves behind the implanted part of the layer 72. It is thus possible to form the control electrode layer 8 in a part of the layer 72 of known concentration and thus to accurately control the sensitivity of the control electrode.

The provision of the metal electrodes, the edge processing and also a possible passivation of the control electrode regions are effected according to conventional prior art.

By virtue of the underlying, continuous n⁺-doped layer 72, the p-conducting control electrode layer 8 of the power semiconductor device according to the invention is always in a field-free zone, even in the blocking state. If said n⁺-doped layer has a sufficiently good transverse conductivity at all points, the power semiconductor device according to the invention behaves like a conventional power diode with a normal, continuous cathode when the control electrode G is short-circuited and connected to the cathode K.

However, if a positive control electrode current is fed in between control electrode G and cathode K, then, in the blocking case, some of the holes injected into the n⁺-doped layer reach the space charge zone 71 and are extracted via the anode A. This brings about a controlled rise in the anodal current. The latter is fed in over a large part of the active area on account of the finely distributed structure, that is to say flows virtually homogeneously through the element without endangering it. From the control unit, the control electrode current is to be fed in merely with respect to a diode forward voltage. However, a delay-free feeding-in of the current in the dynamic case of rapid current commutation requires a correspondingly low-inductance driving, as is described for example for GCT in EP 0 588 026.

The design of the lateral structuring of the cathode is related to that of a turn-off thyristor (GTO, GCT), but their optimum configuration differs significantly. Whereas the emitter injection (electrons) begins and ends in the center of the cathode segments in the GTO, the control electrode injection (holes) begins and ends in the center of the control electrode regions in the case of the power semiconductor device according to the invention. Thus, whereas the main design rule of the GTO demands cathode segments that are ubiquitously of the same width, the design of the power semiconductor device according to the invention is optimal with control electrode tracks that are ubiquitously of the same width. Moreover, the edge of the GTO is embodied without cathode segments for the purpose of current relief, whereas in the case of the power semiconductor device according to the invention the edge should be without control electrode regions in order not to inject any currents there.

The fineness of the control electrode structure depends on the magnitude of the control electrode current to be fed in and on the requisite homogeneity.

If, by way of example, the intention is only to statically compensate for a leakage current, a central, pointwise feeding-in is also appropriate, under certain circumstances. The structure of the cathodal, second main area of such a second embodiment of the power semiconductor device according to the invention is illustrated in FIG. 2 in a plan view of the second main area from above. The cathode electrode is designed in large-area fashion and encloses the control electrode 4 in the center.

The control electrode is not provided for controlling or switching the power semiconductor device according to the invention as an active element. Rather, it is provided for influencing the parameters which characterize the deviation from the ideal diode.

The power semiconductor device according to the invention has various advantageous properties during operation.

In contrast to the standard diode, the reverse recovery current of the power semiconductor device according to the invention can be controlled via the additional control electrode. A positive control electrode current between control electrode and cathode brings about a rise in the anodal current. In the case where the semiconductor body is designed for minimal switching losses, an associated reverse recovery current that falls excessively rapidly can be controlled by means of the control electrode current and thus be taken uniformly to zero. Overvoltages in the converter circuit can thus be avoided.

In the series circuit of diodes without control electrodes, in a switching operation, the different reverse recovery charges of the individual devices can lead to major differences in their voltage loading and ultimately to their destruction. In a series circuit of the power semiconductor devices according to the invention, in the event of an overvoltage, the positive control electrode can be controlled in such a way that the anode-cathode voltage decreases in the case of the given cathode current. It is thus no longer necessary to connect snubbers in parallel with the power semiconductor devices. Although the control of the diode behavior leads to additional losses in the device, they are considerably lower than those in a snubber circuit. A snubber circuit is designed with respect to the maximum switching difference of series-connected diodes and generates a maximum power loss independently of the diode design.

As already mentioned above, the control electrode of the power semiconductor device according to the invention allows the leakage current to be raised in the blocking state. In the steady-state blocking state of a plurality of power semiconductor devices connected in series, the differences between the leakage currents of the individual power semiconductor devices can be compensated for by means of a control electrode current. A control electrode current proportional to the difference between the instantaneous value and the steady-state maximum permissible value of the anode-cathode voltage produces a uniform voltage distribution in the series circuit of the power semiconductor devices according to the invention. In this case, the control electrode current is of the same order of magnitude as the leakage currents of the power semiconductor devices.

During blocking operation of the power semiconductor devices according to the invention, the control electrode can also be operated momentarily with a current of the order of magnitude of the maximum cathode current. This operating mode affords the possibility of using the power semiconductor device according to the invention as a diode back-to-back with respect to active power semiconductors (IGBT, GTO, . . . ) in converter series circuits. Slight differences in the switching behavior of said power semiconductors can lead to a high voltage loading. On series-connected active semiconductors in which the current falls rapidly, the overvoltage can be limited by connecting power semiconductor devices according to the invention in parallel. If the voltage rises too rapidly in the case of an active semiconductor which is loaded with constant current in the turn-off phase, the current can be accepted by the power semiconductor device according to the invention connected back-to-back and the voltage loading on the active semiconductor can thus be limited.

The properties of the power semiconductor device according to the invention have been verified on the basis of measurements both in steady-state and in dynamic operation.

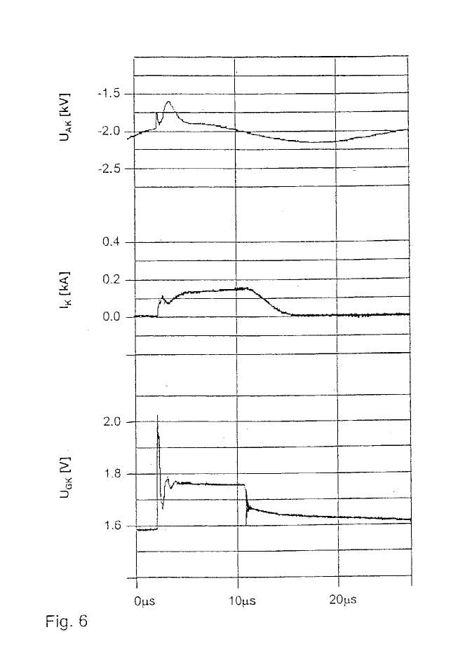

The measurement results on a power semiconductor device according to the invention with a maximum permissible loading of 4500 V/4000 A at a junction temperature of 25° is illustrated in FIG. 5. The diagram shows that the leakage current I_{K} rises proportionally to the positive control electrode current I_{G}. The gain factor is slightly temperature-dependent.

In the series circuit of conventional diodes without a control electrode, a symmetrization of the voltage distribution can be achieved by connecting a resistor in parallel with each diode. Said resistor is dimensioned such that a maximum difference between the leakage currents of two series-connected diodes leads to a limited rise in the voltage loading on the diode. As in the case of the snubber circuit in dynamic operation, considerable losses are produced by the static symmetrization in the resistor connected in parallel, even when the leakage currents of series-connected diodes do not differ.

The use of the power semiconductor devices according to the invention affords the advantage that only a difference between the leakage currents leads to an additional power loss in the converter circuit.

For the measurement of the steady-state properties, a power semiconductor device according to the invention was loaded with a voltage U_{AK} of −2400 V. The pn junction is thus in blocking operation. A positive control electrode current provides for an injection of charge carriers and thus causes the reverse current to increase. FIG. 6 shows the measurement results in this operation mode. At a reverse voltage of −2400 V, the reverse current I_{K} was taken to 150 A by means of a control electrode current generated by a positive voltage U_{GK} at the control electrode. The gain factor between control electrode current and cathode current is approximately 1.

A similar measurement was carried out in the dynamic state of the power semiconductor device according to the invention. The control method of the power semiconductor device according to the invention can be used to limit overvoltages on series-connected devices in the reverse recovery state.

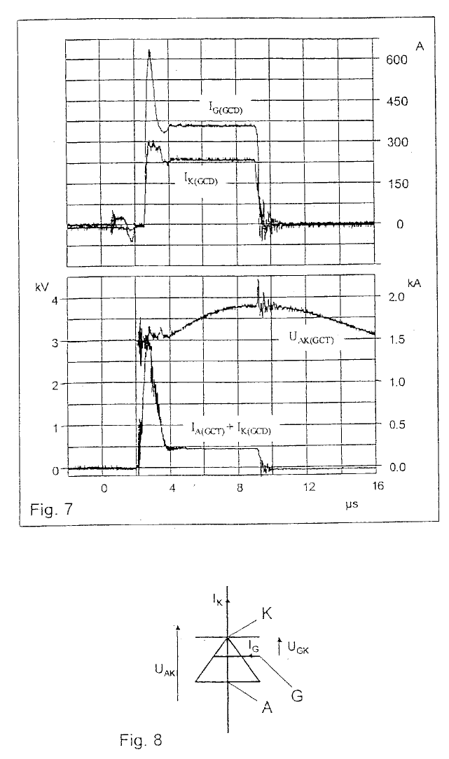

FIG. 7 shows the operation of the power semiconductor device according to the invention connected in parallel with a GCT in the dynamic GCT turn-off process at the operating point 1500 A/3000 V. The control electrode can be controlled with a positive control electrode current as early as before and during the turn-off process. The cathode and control electrode current and also the anode-cathode voltage of the power semiconductor device according to the invention are illustrated in the upper diagram of FIG. 7. The lower diagram illustrates the sum of the cathode current of the power semiconductor device according to the invention and the anode current of the GCT connected in parallel. The tail region of the GCT current profile corresponds to the reverse recovery process in a conventional PSnN diode that has been flooded by charge carriers shortly beforehand. The current in the power semiconductor device according to the invention is proportional to its gate current. It can clearly be discerned that, as long as a positive control electrode current is fed in, the sum of the currents can be controlled in a targeted manner in the tail region, through to the point that it can be kept constant over a relatively long time range. It is only if the control electrode current falls that the tail current also correspondingly falls rapidly to zero.

The reverse recovery behavior can be controlled in this way in the power semiconductor device according to the invention. Overvoltages in series circuits can thus be avoided.

The power semiconductor device according to the invention can also be realized with an anodal control electrode. The latter is provided on a corresponding n⁺-doped control electrode layer which is completely embedded in the anodal p⁺-doped zone.

### LIST OF REFERENCE SYMBOLS

1 Semiconductor body

2 Power electrode, anode

3 Power electrode, cathode

4 Control electrode

5 Insulation

6 Anodal p-doped semiconductor layer

72 Cathodal n-doped semiconductor layer

71 Inner, weakly n-doped semiconductor layer

8 p-doped control electrode layer

21, 31 Power terminals, pressure plates

1. A power semiconductor device, in particular a power diode, comprising:
a semiconductor body (1) having a first main area and a second main area arranged opposite to the first main area, the semiconductor body being divided into two zones (6; 71, 72), the two zones being of different conductivity types and forming a pn junction at the plane of intersection, at least one of the two zones having an inner region (71) that adjoins the plane of intersection and has a lower doping than the remaining region (72) of said zone;
a first power electrode (2) on the first main area and a second power electrode (3) on the second main area, the power electrodes respectively covering at least a part of the main areas and being electrically conductively connected to a respective zone (6; 71, 72);
characterized in that
the power semiconductor device comprises means for dynamically influencing the semiconductor parameters which characterize the deviation from the ideal diode by a feeding of current into a control electrode (4).

2. The power semiconductor device as claimed in claim 1, characterized in that
the means for dynamically influencing the semiconductor parameters which characterize the deviation from the ideal diode comprise at least one control electrode (4) provided on a control layer (8), in which case,
on a part of the second main area, at least one control layer (8) is incorporated into the semiconductor body, which control layer is completely embedded in the adjoining zone (72), the control layer (8) and the adjoining zone (72) being of different conductivity types and forming a pn junction at the interface, and, if the adjoining zone comprises an inner region (71) having a lower doping density, the control layer (8) being isolated from the inner region (71) by a layer of nonreduced doping density of the zone (72) adjoining the control layer, and in that
the control electrode (4), which is electrically insulated from the second power electrode (3), is arranged directly on the control layer (8).

3. The power semiconductor device as claimed in claim 2, characterized in that
the area covered by the second power electrode (3) is larger than the area covered by the control electrode (4).

4. The power semiconductor device as claimed in claim 2, characterized in that
the area covered by the second power electrode (3) is at least 50% larger than the area covered by the control electrode (4).

5. The power semiconductor device as claimed in one of claims 2 to 4, characterized in that
relative to the second power electrode (3), the control electrode (4) is arranged in a manner sunk in a depression in the second main area.

6. The power semiconductor device as claimed in claim 5, characterized in that
the second power electrode (3) is divided into a plurality of partial electrodes which are electrically insulated from one another and can be pressure-contact-connected by means of an electrically conductive pressure plate (31) and are connected by the contact connection to the pressure plate to form an overall electrode.

7. The power semiconductor device as claimed in claim 6, characterized in that
the control electrode (4) arranged in depressed fashion encloses the partial electrodes.

8. A power semiconductor module, comprising
a power semiconductor device as claimed in one of claims 1 to 7,
means for contact-connecting the power electrodes (2, 3), and
means for contact-connecting the control electrode (4).

9. The power semiconductor module as claimed in claim 8, characterized in that
the means for contact-connecting the power electrodes (2, 3) comprise pressure plates (21, 31), which are pressed against the power electrodes and, as a result, are electrically and thermally conductively connected to the power electrodes (2, 3).

10. The power semiconductor module as claimed in claim 8 or 9, characterized in that
the means for contact-connecting the control electrode (4) comprise a control terminal, which is led laterally from the module.
